(19) United States
(12) Patent Application Publication
(10) Pub. No.: US 2026/0280501 A1
(43) Pub. Date: Sep. 17, 2026

(54) AMPLIFIER CIRCUIT AND SWITCHED CAPACITOR CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); The University of Tokyo, Tokyo (JP)

(72) Inventors: Tetsuya IIZUKA, Tokyo (JP); Yo KUMANO, Tokyo (JP); Ximing WANG, Tokyo (JP); Kunihiko NAKAMURA, Nisshin-shi (JP); Yoshikazu FURUTA, Nisshin-shi (JP); Tomohiro NEZUKA, Nisshin-shi (JP)

(21) Appl. No.: 19/542,116

(22) Filed: Feb. 17, 2026

(30) Foreign Application Priority Data
Mar. 11, 2025 (JP) 2025-038366

(51) Int. Cl. H03F 3/45

(52) U.S. Cl. CPC H03F 3/45179; H03F 2203/45551

(57) ABSTRACT

An amplifier circuit includes a first series connection of a first MOSFET, capacitor, and second MOSFET between a power supply and ground. The circuit has a differential input pair with a common-voltage terminal, high-potential terminal, and low-potential terminal. Second and third series connections of a third and fourth MOSFET, and a fifth and sixth MOSFET, are arranged in parallel between the high- and low-potential terminals. Positive-side and negative-side switches connect the common-voltage terminal to nodes between the third and fourth MOSFETs, and between the fifth and sixth MOSFETs. Fourth and fifth series connections of a seventh and eighth MOSFET, and a ninth and tenth MOSFET, are coupled between the high-potential or low-potential terminals and nodes of the first series connection. The second MOSFET and the switches are driven by a first clock signal. Other MOSFETs are driven by clock signals with specified phases and inversion.

### CROSS REFERENCE TO RELATED APPLICATION

This application is based on Japanese Patent Application No. 2025-038366 filed on Mar. 11, 2025, the disclosure of which is incorporated herein by reference.

### TECHNICAL FIELD

The present disclosure relates to an amplifier circuit and a switched capacitor circuit that uses the amplifier circuit.

### BACKGROUND

A floating inverter amplifier (FIA) may not supply power directly to an input differential pair forming an amplifier circuit, but instead eliminate a constant current path by charging and discharging a reservoir capacitor. Thus, low power consumption may be achieved.

### SUMMARY

According to an aspect of the present disclosure, an amplifier circuit includes a first series connection of a first MOSFET, a capacitor, and a second MOSFET, an input differential pair, a fourth series connection of a seventh MOSFET and an eighth MOSFET, and a fifth series connection of a ninth MOSFET and a tenth MOSFET. The first series connection is connected between a power supply and a ground. The input differential pair incudes a common-voltage terminal, a high-potential terminal, a low-potential terminal, a second series connection of a third MOSFET and a fourth MOSFET, a third series connection of a fifth MOSFET and a sixth MOSFET, a positive-side switch, and a negative-side switch. The common-voltage terminal receives a common voltage. The third series connection is connected to the second series connection in parallel between the high-potential terminal and the low-potential terminal. The positive-side switch is located between the common-voltage terminal and a common connection node that is located between the third MOSFET and the fourth MOSFET. The negative-side switch is located between the common-voltage terminal and a common connection node that is located between the fifth MOSFET and the sixth MOSFET. The fourth series connection is connected between the high-potential terminal and a common connection node that is located between the first MOSFET and the capacitor. The fifth series connection is connected between the low-potential terminal and a common connection node that is located between the capacitor and the second MOSFET. The second MOSFET, the positive-side switch, and the negative-side switch may be driven by a first clock signal. The tenth MOSFET may be driven by a second clock signal that is in opposite phase to the first clock signal. The first MOSFET may be driven by an inverted signal of the first clock signal. The eighth MOSFET may be driven by an inverted signal of the second clock signal. The seventh MOSFET and the ninth MOSFET may be complementary, and respective gates of the seventh MOSFET and the ninth MOSFET may be connected to the common-voltage terminal.

### BRIEF DESCRIPTION OF DRAWINGS

FIG. 1 is a circuit diagram of an amplifier circuit according to a first embodiment.

FIG. 2 is a waveform diagram of clock signals φ1 and φ2 for operating the amplifier circuit.

FIG. 3 is a circuit diagram of an amplifier circuit according to a second embodiment.

FIG. 4 is a diagram showing a switched capacitor circuit using the amplifier circuit.

FIG. 5 is a waveform diagram of each clock signal for operating the switched capacitor circuit.

### DETAILED DESCRIPTION

The charging and discharging of a reservoir capacitor in a floating inverter amplifier (FIA) may be performed via a switch whose gate of a field effect transistor (FET) is connected to a common voltage, which is an average voltage of the amplifier’s output voltage. The above-mentioned switch may also be referred to as a quenching switch.

By adopting the above configuration, it is possible to suppress a current flowing through the reservoir capacitor and avoid unnecessary discharge from the reservoir capacitor. Since the power consumption of the FIA is determined by the charging and discharging of the reservoir capacitor, the FIA may achieve low power consumption.

In the above-mentioned configuration, since the charging path for the reservoir capacitor also passes through the quenching switch, the charging current may also be suppressed. Thus, the charging speed of the reservoir capacitor may be reduced.

According to an aspect of the present disclosure, an amplifier circuit includes a first series connection of a first MOSFET, a capacitor, and a second MOSFET, an input differential pair, a fourth series connection of a seventh MOSFET and an eighth MOSFET, and a fifth series connection of a ninth MOSFET and a tenth MOSFET. The first series connection is connected between a power supply and a ground. The input differential pair incudes a common-voltage terminal, a high-potential terminal, a low-potential terminal, a second series connection of a third MOSFET and a fourth MOSFET, a third series connection of a fifth MOSFET and a sixth MOSFET, a positive-side switch, and a negative-side switch. The common-voltage terminal receives a common voltage. The third series connection is connected to the second series connection in parallel between the high-potential terminal and the low-potential terminal. The positive-side switch is located between the common-voltage terminal and a common connection node that is located between the third MOSFET and the fourth MOSFET. The negative-side switch is located between the common-voltage terminal and a common connection node that is located between the fifth MOSFET and the sixth MOSFET. The fourth series connection is connected between the high-potential terminal and a common connection node that is located between the first MOSFET and the capacitor. The fifth series connection is connected between the low-potential terminal and a common connection node that is located between the capacitor and the second MOSFET. The second MOSFET, the positive-side switch, and the negative-side switch are driven by a first clock signal. The tenth MOSFET is driven by a second clock signal that is in opposite phase to the first clock signal. The first MOSFET is driven by an inverted signal of the first clock signal. The eighth MOSFET is driven by an inverted signal of the second clock signal. The seventh MOSFET and the ninth MOSFET are complementary, and respective gates of the seventh MOSFET and the ninth MOSFET are connected to the common-voltage terminal.

With this configuration, the discharging of the capacitor is carried out via the seventh and ninth MOSFETs, which are driven by the common voltage. Thus, the discharging can be suppressed. In contrast, the charging of the capacitor is performed rapidly without passing through the seventh and ninth MOSFETs, resulting in improved charging speed and enhanced circuit operating speed.

### First Embodiment

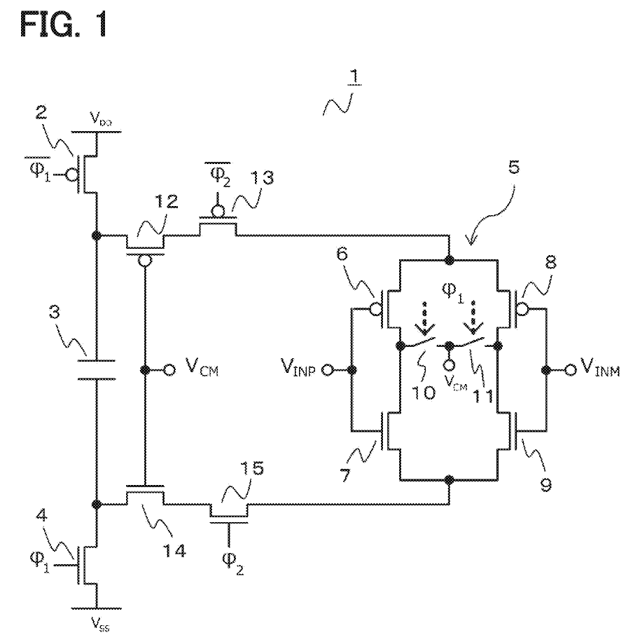

As shown in FIG. 1, a floating inverter amplifier (FIA) 1 according to the present embodiment is an amplifier circuit, and has a series circuit of a P-channel MOSFET 2, a capacitor 3, and an N-channel MOSFET 4 connected between a power supply VDD and a ground VSS. An input differential pair 5 has, between the high potential terminal and the low potential terminal, a series circuit of a P-channel MOSFET 6 and an N-channel MOSFET 7, and a series circuit of a P-channel MOSFET 8 and an N-channel MOSFET 9. Both of the series circuits are connected in parallel. Hereinafter, unless it becomes necessary to refer to the conductivity type after its first appearance, both P-channel MOSFETs and N-channel MOSFETs will simply be referred to as “FETs.”

In the input differential pair 5, the gates of the FETs 6 and 7 serve as a non-inverting input terminal VINP, while the gates of the FETs 8 and 9 serve as an inverting input terminal VINM. The drains of the FETs 6 and 7, which are the positive-side differential output terminals, are connected to the common voltage terminal Vcm via a positive-side switch 10. The drains of the FETs 8 and 9, which are the negative-side differential output terminals, are connected to the common voltage terminal Vcm via a negative-side switch 11.

The common voltage or common-mode voltage is defined as the average voltage between the differential output voltages of the amplifier circuit. In the present embodiment, the average voltage between the common connection node between the FETs 6 and 7 and the common connection node between the FETs 8 and 9 is defined as the common voltage Vcm.

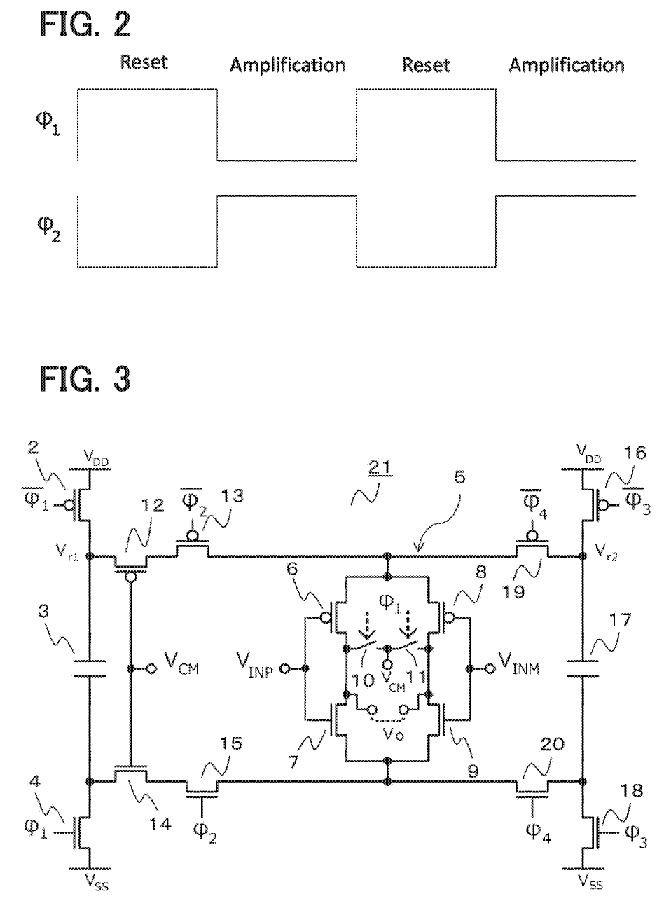

The drain of the FET 2 is connected to the high potential side terminal of the input differential pair 5 via a series circuit of P-channel MOSFETs 12 and 13. The drain of the FET 4 is connected to the low potential side terminal of the input differential pair 5 via a series circuit of N-channel MOSFETs 14 and 15. The FET 4, as well as the switches 10 and 11, are driven by a first clock signal φ1 shown in FIG. 2. The FET 15 is driven by a second clock signal φ2 shown in FIG. 2. These clock signals φ1 and φ2 are signals that are approximately 50% duty cycle and are in opposite phase to each other. Incidentally, in the actual clock signals φ1 and φ2, a period is inserted during which both signals are at a low level while their levels are being switched. It should be noted that the above-mentioned duty cycle is merely an example and is not limited to 50%.

The FET 2 is driven by the inverted signal of the first clock signal φ1, and the FET 13 is driven by the inverted signal of the second clock signal φ2. The gates of the FET 12 and FET 14 are connected to the common voltage terminal Vcm. The FET 12 and FET 14 function as so-called quenching switches.

The FET 2 corresponds to a first MOSFET. The FET 4 corresponds to a second MOSFET. The FET 6 corresponds to a third MOSFET. The FET 7 corresponds to a fourth MOSFET. The FET 8 corresponds to a fifth MOSFET. The FET 9 corresponds to a sixth MOSFET. The FET 12 corresponds to a seventh MOSFET. The FET 13 corresponds to an eighth MOSFET. The FET 14 corresponds to a ninth MOSFET. The FET 15 corresponds to a tenth MOSFET.

The following describes an operation according to the present embodiment. As shown in FIG. 2, the period during which the first clock signal φ1 is at a high level corresponds to a control phase “reset,” and the period during which the first clock signal φ1 is at a low level corresponds to a control phase “amplification.” During the “reset” phase, the FET 2 and FET 4, as well as the switches 10 and 11, are turned on, and the FET 13 and FET15 are turned off, so the capacitor 3 is immediately charged. In addition, the output terminal of the amplifier circuit 1 is connected to the common voltage terminal Vcm.

On the other hand, during the “amplification” phase, the on/off states of each FET and switch are reversed. Accordingly, both ends of the capacitor 3, which has been charged to the power supply VDD, are connected to the high-potential and low-potential terminals of the input differential pair 5 via the FET 12 and FET 13, as well as the FET 14 and FET 15. At this time, the charge stored in the capacitor 3 is gradually discharged through the FET 12 and FET 13, whose gates are connected to the common voltage terminal Vcm.

As described above, according to the FIA 1 according to the present embodiment, a series connection of the FET 2, the capacitor 3, and the FET 4 is connected between the power supply and ground. A series connection of the FET 12 and the FET 13 is connected between the drain of the FET 2 and the high-potential terminal of the input differential pair 5, and a series connection of the FET 14 and the FET 15 is connected between the drain of the FET 4 and the low-potential terminal of the input differential pair 5. The FET 4, the positive-side switch 10, and the negative-side switch 11 of the input differential pair 5 are driven by the first clock signal φ1, while the FET 15 is driven by the second clock signal φ2, which is in opposite phase to the first clock signal. The FET 2 is driven by the inverted signal of the first clock signal φ1, and the FET 13 is driven by the inverted signal of the second clock signal φ2. The gates of the FET 12 and FET 14, which are complementary, are connected to the common voltage terminal Vcm.

With this configuration, the discharging of the capacitor 3 is carried out via the FET 12 and FET 14, which are driven by the common voltage Vcm, so the discharging can be suppressed. The charging of the capacitor 3 is performed rapidly without passing through the FET 12 and FET 14, so the charging speed is enhanced, and the operating speed of the FIA 1 is increased.

### Second Embodiment

Hereinafter, identical reference numerals are assigned to parts that are the same as those in the first embodiment, and explanations thereof will be omitted; only the differing parts will be described. As shown in FIG. 3, an FIA 21 according to the second embodiment is a structure in which additional components are added to the FIA 1. A sixth series connection of a P-channel MOSFET 16, a capacitor 17, and an N-channel MOSFET 18 is connected between the power supply VDD and ground VSS. The drain of the FET 16 is connected to the high potential side terminal of the input differential pair 5 via a P-channel MOSFET 19. The drain of the FET 18 is connected to the low potential side terminal of the input differential pair 5 via an N-channel MOSFET 20.

The FET 18 is driven by a third clock signal φ3, which has the same frequency as the first clock signal φ1 but a different duty cycle. The FET 20 is driven by a fourth clock signal φ4, which is in opposite phase to the third clock signal φ3. The FET 16 is driven by the inverted signal of the third clock signal φ3. The FET 19 is driven by the inverted signal of the fourth clock signal φ4.

The FET 16 corresponds to an eleventh MOSFET. The FET 18 corresponds to a twelfth MOSFET. The FET 19 corresponds to a thirteenth MOSFET. The FET 20 corresponds to a fourteenth MOSFET. Additionally, the capacitor 3 (C1) corresponds to the first capacitor, and the capacitor 17 (C2) corresponds to the second capacitor.

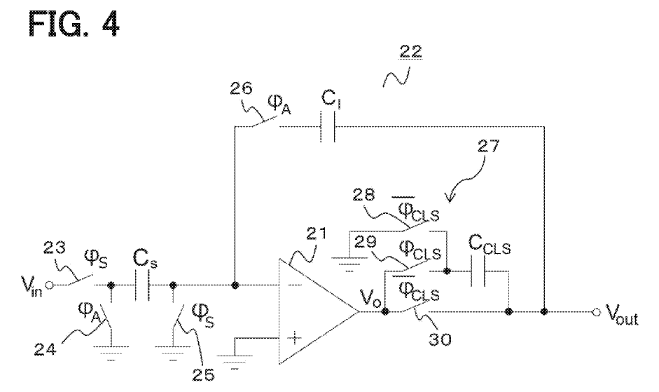

FIG. 4 illustrates a switched capacitor circuit 22 that uses the FIA 21. The FIA 21 is shown with a single-ended symbol, but it is actually a differential type. A series connection of a switch 23 and a sampling capacitor Cs is connected between an input terminal of the switched capacitor circuit 22 and an inverting input terminal of the FIA 21. A switch 24 is connected between one of both ends of the sampling capacitor Cs and an analog ground. A switch 25 is connected between the other of both ends of the sampling capacitor Cs and the analog ground. The non-inverting input terminal of the FIA 21 is connected to the analog ground.

A series connection of a switch 26 and an integration capacitor CI is connected between the inverting input terminal of the FIA 21 and the output terminal of the switched capacitor circuit 22. On the output side of the FIA 21, a correlated level shifting (CLS) unit 27 is provided. In other words, the CLS unit 27 is connected to the output terminal of the FIA 21. A series connection of a CLS capacitor CCLS and a switch 28 is connected between the output terminal of the switched capacitor circuit 22 and the analog ground. A switch 29 is connected between the output terminal of the FIA 21 and one end of the CLS capacitor CCLS. A switch 30 is connected between the output terminal of the FIA 21 and the output terminal of the switched capacitor circuit 22.

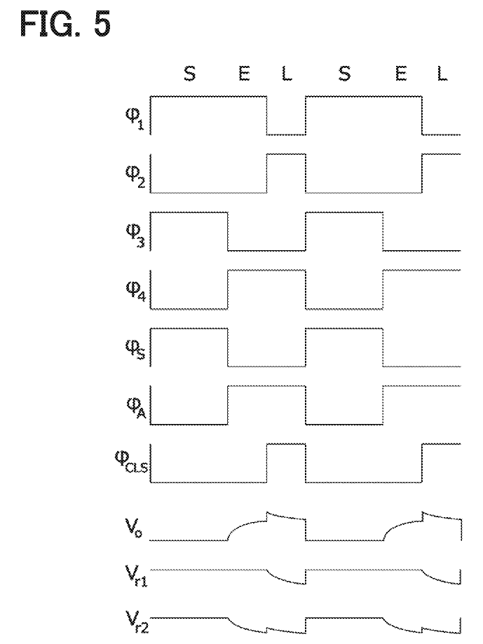

FIG. 5 shows the waveforms of the first to fourth clock signals φ1 to φ4 used for the operation of the FIA 21, the clock signals φs, φA, φCLS used for the operation of the switched capacitor circuit 22, the differential output voltage Vo of the FIA 21, and the drain voltages Vr1 and Vr2 of the FETs 2 and 16 that form the FIA 21. Unlike in the first embodiment, the first clock signal φ1 has a high-level duty ratio of approximately 75%, and the second clock signal φ2 is its inverse phase. The relationship between the third clock signal φ3 and the fourth clock signal φ4 is the same as that between the first clock signal φ1 and the second clock signal φ2 in the first embodiment. The clock signals φS and φA have the same waveform as the third and fourth clock signals φ3 and φ4, respectively, and the clock signal φCLS has the same waveform as the second clock signal φ2. It should be noted that the above duty ratio is merely an example and is not limited to 75%.

As shown in FIG. 5, the switched capacitor circuit 22 is controlled so as to repeatedly perform a sampling (S) phase, an estimation (E) phase, and a level shifting (L) phase.

In the estimation phase, the capacitor 17 is connected to the input differential pair 5. In the level shifting phase, the capacitor 3 is also connected to the input differential pair 5. As a result, the insufficient charge discharged from the capacitor 17 can be supplemented by the capacitor 3, and the CLS capacitor CCLS can be sufficiently charged, thereby improving the effective gain of the FIA 21. As shown in FIG. 5, in the estimation phase, the capacitor 17 is discharged, causing Vr2 to decrease. In the subsequent level shift phase, the capacitor 3 is discharged, causing Vr1 to decrease. In addition, a part of the charge from the capacitor 3 charges the capacitor 17.

The present disclosure has been described in accordance with embodiments, but it is understood that the present disclosure is not limited to these embodiments or structures. The present disclosure also encompasses various modifications and equivalents within the scope of the invention. In addition, various combinations and configurations, as well as other combinations or configurations including only one element, more than one, or fewer than one of those elements, are also within the scope and spirit of the present disclosure.

What is claimed is:

1. An amplifier circuit comprising:
a first series connection of a first MOSFET, a capacitor, and a second MOSFET, the first series connection connected between a power supply and a ground;
an input differential pair including
a common-voltage terminal configured to receive a common voltage,
a high-potential terminal,
a low-potential terminal,
a second series connection of a third MOSFET and a fourth MOSFET,
a third series connection of a fifth MOSFET and a sixth MOSFET, the third series connection connected to the second series connection in parallel between the high-potential terminal and the low-potential terminal,
a positive-side switch located between the common-voltage terminal and a common connection node that is located between the third MOSFET and the fourth MOSFET, and
a negative-side switch located between the common-voltage terminal and a common connection node that is located between the fifth MOSFET and the sixth MOSFET;
a fourth series connection of a seventh MOSFET and an eighth MOSFET, the fourth series connection connected between the high-potential terminal and a common connection node that is located between the first MOSFET and the capacitor; and
a fifth series connection of a ninth MOSFET and a tenth MOSFET, the fifth series connection connected between the low-potential terminal and a common connection node that is located between the capacitor and the second MOSFET, wherein
the second MOSFET, the positive-side switch, and the negative-side switch are configured to be driven by a first clock signal,
the tenth MOSFET is configured to be driven by a second clock signal that is in opposite phase to the first clock signal,
the first MOSFET is configured to be driven by an inverted signal of the first clock signal,
the eighth MOSFET is configured to be driven by an inverted signal of the second clock signal, and
the seventh MOSFET and the ninth MOSFET are complementary, and respective gates of the seventh MOSFET and the ninth MOSFET are connected to the common-voltage terminal.

2. The amplifier circuit according to claim 1, wherein
the capacitor is a first capacitor, the amplifier circuit further comprising:
a sixth series connection of an eleventh MOSFET, a second capacitor and a twelfth MOSFET, the sixth series connection connected between the power supply and the ground;
a thirteenth MOSFET connected between the high-potential terminal and a common connection node that is located between the eleventh MOSFET and the second capacitor; and
a fourteenth MOSFET connected between the low-potential terminal and a common connection node that is located between the second capacitor and the twelfth MOSFET, wherein
the twelfth MOSFET is configured to be driven by a third clock signal that has a same frequency as the first clock signal and a duty ratio different from the first clock signal,
the fourteenth MOSFET is configured to be driven by a fourth clock signal that is in opposite phase to the third clock signal,
the eleventh MOSFET is configured to be driven by an inverted signal of the third clock signal, and
the thirteenth MOSFET is configured to be driven by an inverted signal of the fourth clock signal.

3. A switched capacitor circuit comprising:
the amplifier circuit according to claim 2; and
a correlated level shifting unit located at an output terminal of the amplifier circuit, the correlated level shifting unit configured to operate the amplifier circuit in each of a sampling phase, an estimation phase and a level shifting phase, wherein
in the estimation phase, the second capacitor is connected to the input differential pair in the amplifier circuit, and
in the level shifting phase, the first capacitor and the second capacitor are connected to the input differential pair in the amplifier circuit.
